(19) United States
(12) Patent Application Publication
(10) Pub. No.: US 2025/0167022 A1
(43) Pub. Date: May 22, 2025

(54) SUBSTRATE STANDBY DEVICE, SUBSTRATE PROCESSING SYSTEM, AND SUBSTRATE PROCESSING METHOD

(71) Applicant: Tokyo Electron Limited, Tokyo (JP)

(72) Inventors: Keita Hirase, Koshi City (JP); Koji Tanaka, Koshi City (JP); Yuji Kimura, Koshi City (JP); Shota Takei, Koshi City (JP); Masataka Gosho, Koshi City (JP); Seiji Togawa, Koshi City (JP); Kazuaki Kitamura, Koshi City (JP); Yuji Hagishima, Koshi City (JP); Tomoaki Ohara, Koshi City (JP); Atsushi Egashira, Koshi City (JP)

(21) Appl. No.: 18/949,248

(22) Filed: Nov. 15, 2024

(30) Foreign Application Priority Data
Nov. 16, 2023 (JP) 2023-194973

(51) Int. Cl. H01L 21/67; B08B 3/04; B08B 13/00; G01G 17/04; H01L 21/02; H01L 21/66; H01L 21/683; H01L 21/687

(52) U.S. Cl. CPC H01L 21/67253; B08B 3/04; B08B 13/00; G01G 17/04; H01L 21/02057; H01L 21/67051; H01L 21/6838; H01L 21/68742; H01L 22/12

(57) ABSTRACT

A substrate standby device configured to allow a substrate to standby is provided. The substrate has a first liquid film adhering to a top surface and a bottom surface thereof. The substrate standby device includes a processing liquid supply configured to supply a processing liquid to the top surface of the substrate; a mass measuring device configured to measure a mass of the substrate; a first imaging device configured to acquire a top surface image; and a controller. The controller performs: forming a second liquid film by supplying a first amount of the processing liquid to the top surface of the substrate; measuring a mass of the second liquid film; acquiring the top surface image; and determining a state of the second liquid film based on the top surface image when the mass of the second liquid film is equal to or greater than a first threshold.

### CROSS-REFERENCE TO RELATED APPLICATION

This application claims the benefit of Japanese Patent Application No. 2023-194973 filed on Nov. 16, 2023, the entire disclosures of which are incorporated herein by reference.

### TECHNICAL FIELD

The various aspects and embodiments described herein pertain generally to a substrate standby device, a substrate processing system, and a substrate processing method.

### BACKGROUND

There is known a substrate processing system equipped with a batch processing section, a single-substrate processing section, and an interface section (see, for example, Patent Document 1). The interface section transfers a substrate from the batch processing section to the single-substrate processing section. The interface section has a pure water supply configured to form a liquid film of pure water on a top surface of the substrate, and a load cell configured to measure the mass of the liquid film formed on the top surface of the substrate.

Patent Document 1: Japanese Patent Laid-open Publication No. 2023-129235

### SUMMARY

In an exemplary embodiment, there is provided a substrate standby device configured to allow a substrate to standby. The substrate has a first liquid film adhering to a top surface and a bottom surface thereof. The substrate standby device includes a processing liquid supply configured to supply a processing liquid to the top surface of the substrate; a mass measuring device configured to measure a mass of the substrate; a first imaging device configured to acquire a top surface image, which is an image of the top surface of the substrate; and a controller. The controller performs: forming a second liquid film by supplying, from the processing liquid supply, a first amount of the processing liquid to the top surface of the substrate; measuring a mass of the second liquid film based on the mass of the substrate measured by the mass measuring device; acquiring the top surface image with the first imaging device; and determining a state of the second liquid film based on the top surface image when the mass of the second liquid film is equal to or greater than a first threshold.

The foregoing summary is illustrative only and is not intended to be any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a plan view illustrating a substrate processing system according to an exemplary embodiment;

FIG. 2 is a side view illustrating a second delivery table;

FIG. 3 is a plan view illustrating an example of a stage;

FIG. 4 is a plan view illustrating another example of the stage;

FIG. 5 is a plan view illustrating arrangement of pins;

FIG. 6 is a flowchart showing a substrate processing method according to the exemplary embodiment;

FIG. 7 is a flowchart illustrating a first example of an operation of the second delivery table;

FIG. 8A and FIG. 8B are diagrams (1) illustrating the first example of the operation of the second delivery table;

FIG. 9A and FIG. 9B are diagrams (2) illustrating the first example of the operation of the second delivery table;

FIG. 10A and FIG. 10B are diagrams (3) illustrating the first example of the operation of the second delivery table;

FIG. 11A and FIG. 11B are diagrams (4) illustrating the first example of the operation of the second delivery table;

FIG. 12A and FIG. 12B are diagrams (5) illustrating the first example of the operation of the second delivery table;

FIG. 13A and FIG. 13B are diagrams (6) illustrating the first example of the operation of the second delivery table;

FIG. 14A and FIG. 14B are diagrams (7) illustrating the first example of the operation of the second delivery table;

FIG. 15 is a flowchart illustrating a second example of the operation of the second delivery table;

FIG. 16A and FIG. 16B are diagrams (1) illustrating the second example of the operation of the second delivery table;

FIG. 17A and FIG. 17B are diagrams (2) illustrating the second example of the operation of the second delivery table;

FIG. 18A and FIG. 18B are diagrams (3) illustrating the second example of the operation of the second delivery table;

FIG. 19A and FIG. 19B are diagrams (4) illustrating the second example of the operation of the second delivery table;

FIG. 20A and FIG. 20B are diagrams (5) illustrating the second example of the operation of the second delivery table;

FIG. 21A and FIG. 21B are diagrams (6) illustrating the second example of the operation of the second delivery table;

FIG. 22A and FIG. 22B are diagrams (7) illustrating the second example of the operation of the second delivery table;

FIG. 23 is a flowchart illustrating a third example of an operation of the second delivery table;

FIG. 24A and FIG. 24B are diagrams (1) illustrating the third example of the operation of the second delivery table;

FIG. 25A and FIG. 25B are diagrams (2) illustrating the third example of the operation of the second delivery table;

FIG. 26A and FIG. 26B are diagrams (3) illustrating the third example of the operation of the second delivery table;

FIG. 27A and FIG. 27B are diagrams (4) illustrating the third example of the operation of the second delivery table;

FIG. 28A and FIG. 28B are diagrams (5) illustrating the third example of the operation of the second delivery table; and

FIG. 29A and FIG. 29B are diagrams (6) illustrating the third example of the operation of the second delivery table.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, non-limiting exemplary embodiments of the present disclosure will be described with reference to the accompanying drawings, which form a part hereof. In the various drawings, same or corresponding parts will be assigned same or corresponding reference numerals, and redundant descriptions thereof will be omitted.

### Substrate Processing System

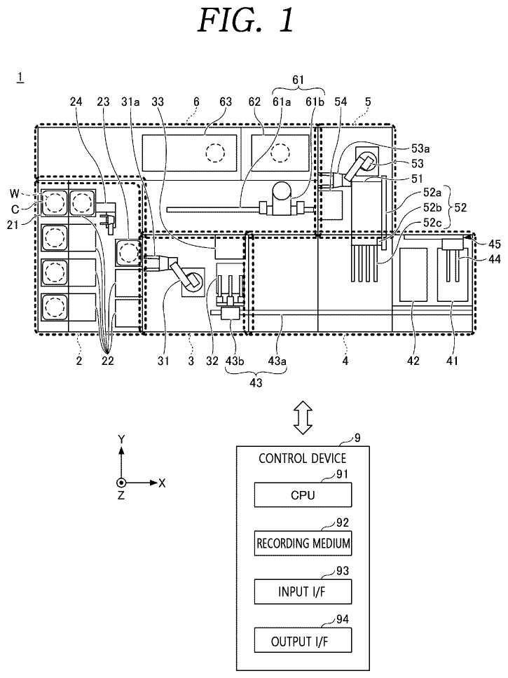

Referring to FIG. 1, a substrate processing system 1 according to an exemplary embodiment will be described. FIG. 1 is a plan view illustrating the substrate processing system 1 according to the exemplary embodiment.

As depicted in FIG. 1, the substrate processing system 1 has a carry-in/out section 2, a first interface section 3, a batch processing section 4, a second interface section 5, a single-substrate processing section 6, and a control device 9.

The carry-in/out section 2 serves as both a carry-in section and a carry-out section. This allows the substrate processing system 1 to be compact-sized. The carry-in/out section 2 has a load port 21, a stocker 22, a loader 23, and a cassette transfer device 24.

The load port 21 is disposed on the negative X-axis side of the carry-in/out section 2. A plurality of (e.g., four) load ports 21 are disposed along the Y-axis direction. However, the number of the load ports 21 is not particularly limited. A cassette C is placed on the load port 21. The cassette C accommodates therein a plurality of (e.g., 25 sheets of) substrates W, and is carried to/from the load port 21. In the cassette C, the substrates W are held horizontally, and are arranged in a vertical direction at a second pitch P2 (P2=N×P1) that is N times a first pitch P1. Here, N is a natural number equal to or greater than 2. In the present exemplary embodiment, N is 2, but it may be three or more.

The stocker 22 is plural in number (for example, four), and they are arranged along the Y-axis direction at the center of carry-in/out section 2 in the X-axis direction. A plurality of (e.g., two) stockers 22 are arranged adjacent to the first interface section 3 along the Y-axis direction on the positive X-axis side of the carry-in/out section 2. The stockers 22 may be arranged in multiple levels in the vertical direction. The stockers 22 temporarily store therein the cassette C accommodating the substrates W before being subjected to cleaning, the empty cassette C from which the substrates W have been taken out, and so forth. The number of the stockers 22 is not particularly limited.

The loader 23 is positioned adjacent to the first interface section 3, and is disposed on the positive X-axis side of the carry-in/out section 2. The cassette C is placed on the loader 23. The loader 23 is provided with a cover opening/closing mechanism (not shown) for opening and closing a cover of the cassette C. The loader 23 may be plural in number. In this case, the loaders 23 may be arranged in multiple levels in the vertical direction.

The cassette transfer device 24 is configured to transfer the cassette C between the load port 21, the stocker 22, and the loader 23. The cassette transfer device 24 is, for example, a multi-joint transfer robot.

The first interface section 3 is disposed on the positive X-axis side of the carry-in/out section 2. The first interface section 3 transfers the substrate W between the carry-in/out section 2, the batch processing section 4, and the single-substrate processing section 6. The first interface section 3 has a substrate moving/placing device 31, a lot forming device 32, and a first delivery table 33.

The substrate moving/placing device 31 is configured to transfer the substrate W between the cassette C placed on the loader 23, the lot forming device 32, and the first delivery table 33. The substrate moving/placing device 31 is configured by a multi-axis (for example, six-axis) arm robot, and has a substrate holding arm 31a at a leading end thereof. The substrate holding arm 31a has a plurality of holding claws (not shown) capable of holding a plurality of (e.g., 25 sheets of) substrates W. The substrate holding arm 31a can take any position and any posture in a three-dimensional space while holding the substrates W with the holding claws.

The lot forming device 32 is disposed on the positive X-axis side of the first interface section 3. The lot forming device 32 holds a multiple number of substrates W at the first pitch P1 to form a lot L.

The first delivery table 33 is adjacent to the single-substrate processing section 6, and is disposed on the positive Y-axis side of the first interface section 3. The first delivery table 33 receives the substrate W from a fourth transfer device 61 and temporarily stores the received substrate W thereon until it is handed over to the carry-in/out section 2.

The batch processing section 4 is disposed on the positive X-axis side of the first interface section 3. That is, the carry-in/out section 2, the first interface section 3, and the batch processing section 4 are disposed in this order from the negative X-axis side toward the positive X-axis side. The batch processing section 4 collectively processes the lot L which includes a multiple number of (e.g., 50 or 100 sheets of) substrates W at the first pitch P1. The single lot L is composed of substrates W of, for example, M cassettes C. M is a natural number equal to or greater than 2. M may be the same number as N, or may be a different number. The batch processing section 4 has a chemical liquid tub 41, a rinse liquid tub 42, a first transfer device 43, a handling tool 44, and a driving device 45.

The chemical liquid tub 41 and the rinse liquid tub 42 are arranged along the X-axis direction. For example, the chemical liquid tub 41 and the rinse liquid tub 42 are arranged in this order from the positive X-axis side toward the negative X-axis side. The chemical liquid tub 41 and the rinse liquid tub 42 are also collectively referred to as a processing tub. The number of the chemical liquid tub 41 and the rinse liquid tub 42 is not limited to the example shown in FIG. 1. For example, although a single set of chemical liquid tub 41 and rinse liquid tub 42 is provided in FIG. 1, multiple sets may be provided.

The chemical liquid tub 41 stores therein a chemical liquid in which the lot L is to be immersed. The chemical liquid is, by way of non-limiting example, a phosphoric acid aqueous solution (H₃PO₄). The phosphoric acid aqueous solution selectively etches and removes a silicon nitride film among a silicon oxide film and the silicon nitride film. The chemical liquid is not limited to the phosphoric acid aqueous solution. For example, it may be DHF (dilute hydrofluoric acid), BHF (a mixture of hydrofluoric acid and ammonium fluoride), dilute sulfuric acid, SPM (a mixture of sulfuric acid, hydrogen peroxide, and water), SC1 (a mixture of ammonia, hydrogen peroxide, and water), SC2 (a mixture of hydrochloric acid, hydrogen peroxide, and water), TMAH (a mixture of tetramethylammonium hydroxide and water), a plating liquid, or the like. The chemical liquid may be one for peeling or plating. The number of the chemical liquid(s) is not particularly limited, and a plurality of chemical liquids may be used.

The rinse liquid tub 42 stores therein a first rinse liquid in which the lot L is to be immersed. The first rinse liquid is pure water that removes the chemical liquid from the substrate W. For example, it may be DIW (deionized water).

The first transfer device 43 has a guide rail 43a and a first transfer arm 43b. The guide rail 43a is disposed on the further negative Y-axis side than the processing tub. The guide rail 43a extends in a horizontal direction (X-axis direction) from the first interface section 3 to the batch processing section 4. The first transfer arm 43b is configured to move in the horizontal direction (X-axis direction) along the guide rail 43a. The first transfer arm 43b may move in a vertical direction or rotate around a vertical axis. The first transfer arm 43b transfers the lot L at once between the first interface section 3 and the batch processing section 4.

The handling tool 44 receives the lot L from the first transfer arm 43b, and holds it. The handling tool 44 holds the multiple number of substrates W at the first pitch P1 in the Y-axis direction, and holds each of the substrates W vertically.

The driving device 45 is configured to move the handling tool 44 in the X-axis direction and the Z-axis direction. The handling tool 44 immerses the lot L in the chemical liquid stored in the chemical liquid tub 41, then immerses the lot L in the first rinse liquid stored in the rinse liquid tub 42, and then hands the lot L over to the first transfer device 43.

In the present exemplary embodiment, one set of handling tool 44 and driving device 45 is provided. However, multiple sets may be provided. In the latter case, one set may immerse the lot L in the chemical liquid stored in the chemical liquid tub 41, and another set may immerse the lot L in the first rinse liquid stored in the rinse liquid tub 42. In this case, the driving device 45 only needs to move the handling tool 44 in the Z-axis direction, and does not need to move the handling tool 44 in the X-axis direction.

The second interface section 5 is disposed on the positive Y-axis side of the batch processing section 4. The second interface section 5 transfers the substrate W between the batch processing section 4 and the single-substrate processing section 6. The second interface section 5 has an immersion tub 51, a second transfer device 52, a third transfer device 53, and a second delivery table 54.

The immersion tub 51 is disposed outside the movement range of the first transfer arm 43b. For example, the immersion tub 51 is disposed at a position shifted to the positive Y-axis side with respect to the processing tub. The immersion tub 51 stores therein a second rinse liquid in which the lot L is to be immersed. The second rinse liquid is, for example, DIW (deionized water). The substrate W is kept in the second rinse liquid until it is lifted up from the second rinse liquid by the third transfer device 53. Since the substrate W exists below the liquid level of the second rinse liquid, a surface tension of the second rinse liquid does not act on the substrate W, so a collapse of an irregularity pattern of the substrate W can be suppressed.

The second transfer device 52 has a Y-axis driving device 52a, a Z-axis driving device 52b, and a second transfer arm 52c.

The Y-axis driving device 52a is disposed on the positive X-axis side of the second interface section 5. The Y-axis driving device 52a extends horizontally (in the Y-axis direction) from the second interface section 5 to the batch processing section 4. The Y-axis driving device 52a moves the Z-axis driving device 52b and the second transfer arm 52c in the Y-axis direction. The Y-axis driving device 52a may include a ball screw.

The Z-axis driving device 52b is movably mounted to the Y-axis driving device 52a. The Z-axis driving device 52b is configured to move the second transfer arm 52c in the Z-axis direction. The Z-axis driving device 52b may include a ball screw.

The second transfer arm 52c is movably mounted to the Z-axis driving device 52b. The second transfer arm 52c receives the lot L from the first transfer arm 43b and holds it. The second transfer arm 52c holds the multiple number of substrates W at the first pitch P1 in the Y-axis direction, and holds each of the multiple number of substrates W vertically. The second transfer arm 52c is moved in the Y-axis direction and the Z-axis direction by the Y-axis driving device 52a and the Z-axis driving device 52b. The second transfer arm 52c is configured to be movable between multiple positions including a delivery position, an immersion position, and a standby position.

The delivery position is a position where the lot L is handed over between the first transfer arm 43b and the second transfer arm 52c. The delivery position is a position on the negative Y-axis and positive Z-axis side.

The immersion position is a position where the lot L is immersed in the immersion tub 51. The immersion position is a position on the positive Y-axis and negative Z-axis side with respect to the delivery position.

The standby position is a position where the second transfer arm 52c stands by when neither the delivery of the lot L nor the immersion of the lot L in immersion tub 51 is being performed. The standby position is directly below the delivery position (negative Z-axis side thereof) and is a position where the second transfer arm 52c does not impede the movement of the first transfer arm 43b. In this case, as the second transfer arm 52c can be moved to the delivery position only by being moved upwards (toward the positive Z-axis side), throughput can be improved. The standby position may be the same position as the immersion position. In this case, it is possible to suppress particles that may be generated due to the operation of the first transfer device 43 from adhering to the second transfer arm 52c. The standby position may be a position directly above the immersion position (positive Z-axis side thereof). In this way, by setting the standby position to the position different from the delivery position, the first transfer arm 43b and the second transfer arm 52c can be suppressed from coming into contact with each other.

The second transfer device 52 moves the second transfer arm 52c to the immersion position or the standby position while the first transfer device 43 is being operated. This suppresses the first transfer arm 43b and the second transfer arm 52c from coming into contact with each other.

The third transfer device 53 is composed of a multi-axis (e.g., six-axis) arm robot, and has a third transfer arm 53a at a leading end thereof. The third transfer arm 53a has a holding claw (not shown) capable of holding a single sheet of substrate W. The third transfer arm 53a can take any position and any posture in a three-dimensional space while holding the substrate W with the holding claw. The third transfer device 53 transfers the substrate W between the second transfer arm 52c located at the immersion position and the second delivery table 54. At this time, since the immersion tub 51 is disposed outside the movement range of the first transfer arm 43b, the first transfer arm 43b and the third transfer arm 53a do not interfere with each other. This allows one of the first transfer device 43 and the third transfer device 53 to be operated independently of an operational status of the other. Therefore, the first transfer device 43 and the third transfer device 53 can be operated at any timing, so that the time required for the transfer of the substrate W can be shortened. As a result, productivity of the substrate processing system 1 is improved.

The second delivery table 54 is adjacent to the single-substrate processing section 6 and is disposed on the negative X-axis side of the second interface section 5. The second delivery table 54 receives the substrate W from the third transfer devices 53, and temporarily stores the received substrate W thereon until it is delivered to the single-substrate processing section 6. The substrate W taken out of the immersion tub 51 is placed on the second delivery table 54. Desirably, the substrate W placed on the second delivery table 54 is in a state where its surface is wet with the second rinse liquid, for example. In this case, the surface tension of the second rinse liquid does not act on the substrate W, so that the collapse of the irregularity pattern of the substrate W can be suppressed. The number of the second delivery table 54 may be one or more. Details of the second delivery table 54 will be described later.

The single-substrate processing section 6 is disposed on the negative X-axis side of the second interface section 5 and the positive Y-axis side of the carry-in/out section 2, the first interface section 3, and the batch processing section 4. single-substrate processing section 6 processes the substrates W one by one. The single-substrate processing section 6 has the fourth transfer device 61, a liquid processing apparatus 62, and a drying apparatus 63.

The fourth transfer device 61 has a guide rail 61a and a fourth transfer arm 61b. The guide rail 61a is disposed on the negative Y-axis side of the single-substrate processing section 6. The guide rail 61a extends in a horizontal direction (X-axis direction) in the single-substrate processing section 6. The fourth transfer arm 61b moves in the horizontal direction (X-axis direction) along the guide rail 61a and a vertical direction, and also rotates around a vertical axis. The fourth transfer arm 61b transfers the substrate W between the second delivery table 54, the liquid processing apparatus 62, the drying apparatus 63, and the first delivery table 33. The number of the fourth transfer arm 61b may be one or more, and in the latter case, the fourth transfer device 61 transfers a plurality of (e.g., five) substrates W at once.

The liquid processing apparatus 62 is disposed on the positive X-axis side and positive Y-axis side of the single-substrate processing section 6. The liquid processing apparatus 62 is of a single substrate type, and it processes the substrates W one by one with a processing liquid. The liquid processing apparatus 62 is plural in number, and they are arranged in multiple levels (e.g., three levels) in the vertical direction (Z-axis direction). This allows a plurality of substrates W to be processed simultaneously with the processing liquid. The processing liquid may be plural in number. For example, pure water such as DIW, and a drying liquid having a bottom surface tension than pure water may be used. The drying liquid may be, by way of non-limiting example, alcohol such as IPA (isopropyl alcohol).

The drying apparatus 63 is disposed adjacent to the liquid processing apparatus 62 on the negative X-axis side thereof. In this case, an end face of the single-substrate processing section 6 on the positive Y-axis side may be disposed so as to be on a level with or on a substantially level with an end face of the second interface section 5 on the positive Y-axis side. This results in almost no dead space, so that the footprint of the substrate processing system 1 can be made small. In contrast, if the drying apparatus 63 is disposed adjacent to the liquid processing apparatus 62 on the positive Y-axis side thereof, the end face of the single-substrate processing section 6 on the positive Y-axis side may protrude more than the end face of the second interface section 5 on the positive Y-axis side, resulting in the dead space. The drying apparatus 63 is of a single substrate type, and dries the substrates W one by one with a supercritical fluid. The drying apparatus 63 is plural in number, and they are arranged in multiple levels (e.g., three levels) in the vertical direction. With this configuration, the multiple substrates W can be dried simultaneously.

Here, both the liquid processing apparatus 62 and the drying apparatus 63 do not need to be of the single substrate type, and the liquid processing apparatus 62 may be of the single substrate type while the drying apparatus 63 is of a batch type. The drying apparatus 63 may dry a plurality of substrates W collectively with the supercritical fluid. The number of the substrates W collectively processed in the drying apparatus 63 may be equal to or more than the number of the substrates W collectively processed in the liquid processing apparatus 62, but may be less than that. An apparatus other than the liquid processing apparatus 62 and the drying apparatus 63 may be disposed in the single-substrate processing section 6.

The control device 9 is, for example, a computer, and includes a CPU (Central Processing Unit) 91 and a recording medium 92 such as a memory. The recording medium 92 stores a program that controls various processes performed in the substrate processing system 1. The control device 9 controls the operation of the substrate processing system 1 by causing the CPU 91 to execute the program stored in the recording medium 92. The control device 9 includes an input interface 93 and an output interface 94. The control device 9 receives a signal from the outside through the input interface 93 and transmits a signal to the outside through the output interface 94.

The aforementioned program is stored, for example, in a computer-readable recording medium, and is installed from that recording medium into the recording medium 92 of the control device 9. The computer-readable recording medium may be, by way of non-limiting example, a hard disk (HD), a flexible disk (FD), a compact disk (CD), a magnet optical disk (MO), a memory card, or the like. The program may also be downloaded from a server via the Internet and installed into the recording medium 92 of the control device 9. The control device 9 is an example of a controller, and it functions as a part of a substrate standby device.

In the substrate processing system 1, the substrate W is transferred from the carry-in/out section 2 to the first interface section 3, the batch processing section 4, the second interface section 5, and the single-substrate processing section 6 in this order, and is then returned back to the carry-in/out section 2.

### Details of Second Delivery Table

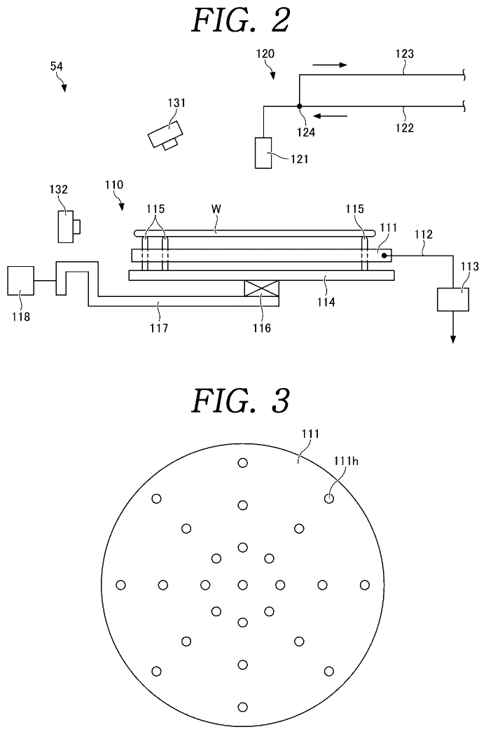

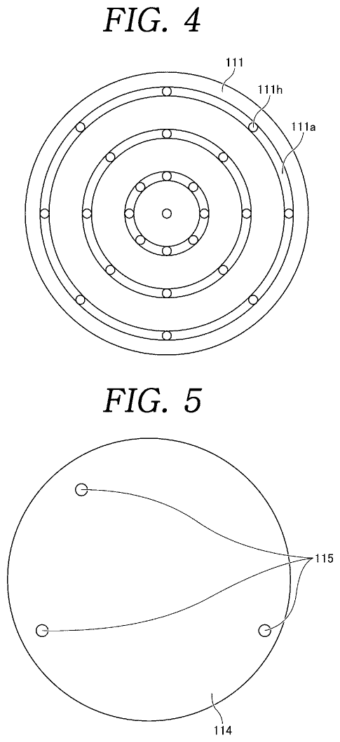

A detailed configuration of the second delivery table 54 will be described with reference to FIG. 2 to FIG. 5. FIG. 2 is a side view illustrating the second delivery table 54. FIG. 3 is a plan view illustrating an example of a stage 111. FIG. 4 is a plan view illustrating another example of the stage 111. FIG. 5 is a plan view illustrating the layout of pins 115.

As depicted in FIG. 2, the second delivery table 54 includes a substrate holder 110, a pure water supply 120, a first imaging device 131, and a second imaging device 132.

The substrate holder 110 has the stage 111, a suction path 112, an ejector 113, a pin supporting member 114, the plurality of pins 115, a load cell 116, an arm 117, and a driving source 118.

The stage 111 has a circular disk shape. The stage 111 holds the substrate W horizontally. The stage 111 is provided with a plurality of suction holes 111h, as shown in FIG. 3. The plurality of suction holes 111h suck and remove a first liquid film LF1 attached to a bottom surface of the substrate W. The plurality of suction holes 111h also serve to attract the substrate W. The respective suctions holes 111h are configured to communicate with the one and the same suction path 112 so that their suction forces are adjustable all at once. Alternatively, the respective suction holes 111h may be configured to communicate with different suction paths 112 so that their suction forces can be adjusted individually. In this case, it is easy to attract the substrate W which is bent. By way of example, when the substrate W is bent so as to project upwards, the substrate W can be easily attracted by sequentially starting the suction from an outer periphery of the stage 111 toward a center thereof. As another example, when the substrate W is bent so as to project downwards, the substrate W can be easily attracted by sequentially starting the suction from the center of the stage 111 toward the outer periphery thereof. The plurality of suction holes 111h may be arranged in a concentric shape or in a radial shape. The number and the layout of the plurality of suction holes 111h are not limited to the example shown in FIG. 3.

The stage 111 may have a plurality of grooves 111a that are arranged in a concentric shape, as shown in FIG. 4. The suction holes 111h are formed on a bottom surface of any one of the plurality of grooves 111a. The corresponding suction holes 111h communicate with the corresponding one of the plurality of grooves 111a at a top end thereof. Since the stage 111 has the plurality of grooves 111a, it is easy to uniformly suction the substrate W.

The suction path 112 allows the plurality of suction holes 111h to communicate with the ejector 113. The suction path 112 functions as a part of a suction mechanism.

The ejector 113 is configured to suck the first liquid film LF1 attached to the bottom surface of the substrate W through the plurality of suction holes 111h and the suction path 112, and also serves to attract the substrate W on top of the stage 111. The ejector 113 functions as a part of the suction mechanism.

The pin supporting member 114 is disposed below the stage 111. The pin supporting member 114 has a circular plate shape. The pin supporting member 114 supports the plurality of pins 115.

The plurality of pins 115 are provided on the pin supporting member 114. The number of the pins 115 is, for example, three, as shown in FIG. 3. However, the number of the pins 115 may be four or more. The plurality of pins 115 support the substrate W from below above the pin supporting member 114.

The load cell 116 is provided at a leading end of the arm 117. The pin supporting member 114 is disposed on the load cell 116. The load cell 116 is configured to measure a mass including the pin supporting member 114, the pins 115, and the substrate W. The load cell 116 is an example of a mass measuring device.

The arm 117 supports the load cell 116.

The driving source 118 is configured to move the arm 117 up and down. As a result, the arm 117, the load cell 116, the pin supporting member 114, the pins 115, and the substrate W are raised and lowered with respect to the stage 111. The driving source 118 may include a stepping motor.

The pure water supply 120 has a nozzle 121, a pure water supply line 122, and a return line 123. The pure water supply line 122 is connected to the nozzle 121. The nozzle 121 is configured to discharge pure water supplied through the pure water supply line 122. The pure water supply line 122 has a branch point 124. The return line 123 is connected to this branch point 124. Even during a period when the discharge of the pure water from the nozzle 121 is not being performed, the pure water flows in the return line 123 and a portion of the pure water supply line 122 upstream of the branch point 124. The pure water supply 120 is configured to supply a first amount of pure water to the top surface of the substrate W and forms a second liquid film LF2, which is a liquid film of the pure water, on the top surface of the substrate W. The pure water supply 120 is an example of a processing liquid supply.

The first imaging device 131 is disposed above the stage 111. The first imaging device 131 is configured to image the top surface of the substrate W placed on the stage 111 and the substrate W supported by the plurality of pins 115 to acquire a top surface image, which is an image of the top surface of the substrate W. The first imaging device 131 may include a camera and generate the image by the camera. The first imaging device 131 may include a laser light source and a camera, and may generate the image by an optical cutting method. In the example of FIG. 2, only one first imaging device 131 is provided. However, there may be provided two or more first imaging devices 131.

The second imaging device 132 is provided on a lateral side of the stage 111. The second imaging device 132 is configured to image the bottom surface of the substrate W supported on the pins 115 to acquire a bottom surface image, which is an image of the bottom surface of the substrate W. The second imaging device 132 may include a camera and may generate the image by the camera. The second imaging device 132 may include a laser light source and a camera, and may generate the image by the optical cutting method. Although only one second imaging device 132 is provided in the example of FIG. 2, two ore more second imaging devices 132 may be provided.

The second delivery table 54 described above functions as a part of the substrate standby device.

### Operation of Substrate Processing System

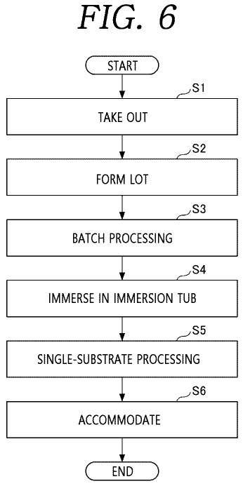

Referring to FIG. 6, the operation of the substrate processing system 1 according to the exemplary embodiment, that is, a substrate processing method will be explained. FIG. 6 is a flowchart illustrating the substrate processing method according to the present exemplary embodiment. Processes shown in FIG. 6 are performed under the control of the control device 9.

First, the cassette C accommodating the plurality of substrates W is carried into the carry-in/out section 2 and placed on the load port 21. In the cassette C, the substrates W are held horizontally, and vertically arranged at the second pitch P2 (P2=N×P1). N is a natural number equal to or greater than 2. In the present exemplary embodiment, N is 2, but it may be 3 or more.

Next, the cassette transfer device 24 transfers the cassette C from the load port 21 to the loader 23. The cover of the cassette C transferred to the loader 23 is opened by the cover opening/closing mechanism.

Next, the substrate moving/placing device 31 receives the substrates accommodated in the cassette C (S1 in FIG. 6), and transfers the received substrates W to the lot forming device 32.

Then, the lot forming device 32 holds a multiple number of substrates W at the first pitch P1 (P1=P2/N) to form the lot L (S2 in FIG. 6). The single lot L is composed of substrates W in, for example, M cassettes C. Since the pitch of the substrates W is reduced from the second pitch P2 to the first pitch P1, the number of the substrates W to be processed at one time can be increased.

Next, the first transfer device 43 receives the lot L from the lot forming device 32 and transfers it to the handling tool 44.

Then, the handling tool 44 descends from above the chemical liquid tub 41, immerses the lot L in the chemical liquid, and performs a chemical liquid process (S3 of FIG. 6). Thereafter, the handling tool 44 rises to lift up the lot L from the chemical liquid, and then is moved horizontally (in the negative X-axis direction) toward above the rinse liquid tub 42.

Subsequently, the handling tool 44 descends from above the rinse liquid tub 42, immerses the lot L in the first rinse liquid, and performs a rinse liquid process (S3 of FIG. 6). Thereafter, the handling tool 44 ascends to lift up the lot L out of the first rinse liquid. Then, the first transfer device 43 receives the lot L from the handling tool 44, and transfers it to the second transfer device 52.

Next, the second transfer arm 52c of the second transfer device 52 is moved horizontally (in the positive Y-axis direction) and lowered from above the immersion tub 51 to immerse the lot L in the second rinse liquid (S4 in FIG. 6). The substrates W of the lot L are maintained in the second rinse liquid until they are lifted up from the second rinse liquid by the third transfer device 53. Since the substrates W are present below the liquid level of the second rinse liquid, the surface tension of the second rinse liquid does not act on the substrates W, so that a collapse of the irregularity pattern of the substrates W can be suppressed.

Thereafter, the third transfer device 53 transfers the substrates W of the lot L held by the second transfer arm 52c in the second rinse liquid to the second delivery table 54. For example, the third transfer device 53 transfers the substrates W one by one to the second delivery table 54.

Next, the fourth transfer device 61 receives the substrate W from the second delivery table 54, and transfers them to the liquid processing apparatus 62.

Then, the liquid processing apparatus 62 processes the substrates W one by one with a liquid (S5 of FIG. 6). The liquid may be plural in number, and these liquids may be, by way of non-limiting example, pure water such as DIW and a drying liquid having a bottom surface tension than the pure water. The drying liquid may be, for example, alcohol such as IPA. The liquid processing apparatus 62 supplies the pure water and the drying liquid in this order onto the top surface of the substrate W to form a liquid film of the drying liquid.

Subsequently, the fourth transfer device 61 receives the substrate W from the liquid processing apparatus 62, and holds the substrate W horizontally with their liquid films of the drying liquid facing upwards. The fourth transfer device 61 then transfers the substrate W from the liquid processing apparatus 62 to the drying apparatus 63.

Afterwards, the drying apparatus 63 dries the substrates W one by one with a supercritical fluid (S5 of FIG. 6). The drying liquid may be replaced with the supercritical fluid so a collapse of the irregularity pattern of the substrate W due to the surface tension of the drying liquid can be suppressed. Since the supercritical fluid requires a pressure-resistant container, the drying process is performed as a single-substrate process rather than a batch process in order to size down the pressure-resistant container.

Although the drying apparatus 63 is of the single-substrate type in the present exemplary embodiment, it may be of a batch type as mentioned above. The batch type drying apparatus 63 dries the multiple substrates W having the liquid films all at once with the supercritical fluid. While the single-substrate type drying apparatus 63 has one transfer arm configured to hold the substrates W, the batch type drying apparatus 63 has multiple transfer arms.

Next, the fourth transfer device 61 receives the substrates W from the drying apparatus 63, and transfers them to the first delivery table 33.

Then, the substrate moving/placing device 31 receives the substrates W from the first delivery table 33 and stores them in the cassette C (S6 of FIG. 6). The cassette C accommodating the substrates W is carried out from the carry-in/out section 2.

### Operation of Second Delivery Table

### First Example

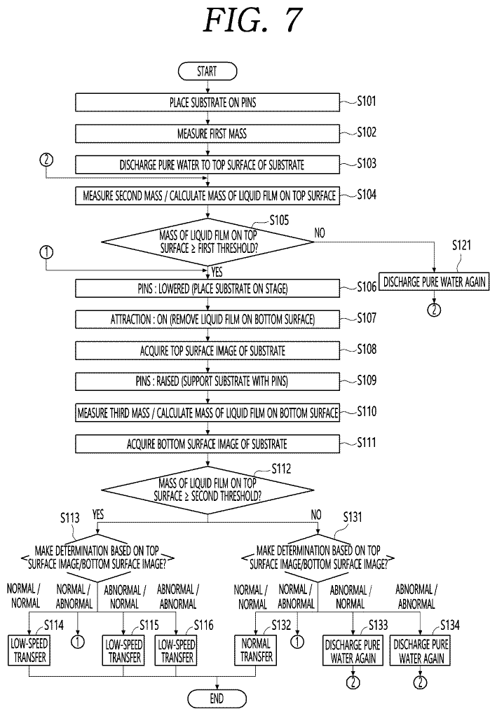

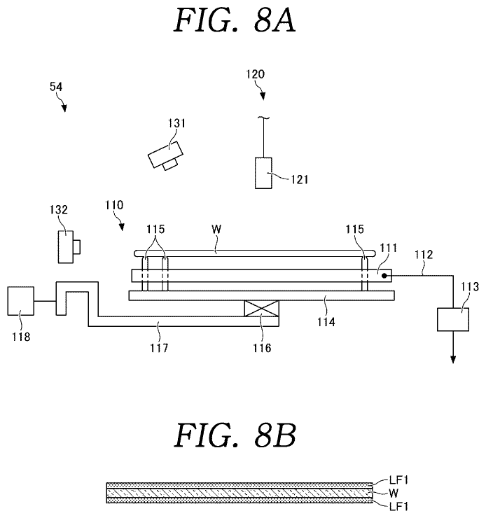

A first example of the operation of the second delivery table 54 will be described with reference to FIG. 7 to FIG. 14B. FIG. 7 is a flowchart illustrating the first example of the operation of the second delivery table 54. FIG. 8A to FIG. 14B are diagrams showing the first example of the operation of the second delivery table 54. In FIG. 8A to FIG. 14B, the diagrams assigned A are side views showing the second delivery table 54, and the diagrams assigned B are cross sectional views of the substrate W shown in the diagrams assigned A. The processing shown in FIG. 7 is performed under the control of the control device 9.

In a process S101, when the substrate W is transferred to the second delivery table 54 by the third transfer device 53, the substrate W is disposed on the three pins 115 as shown in FIG. 8A. At this time, as illustrated in FIG. 8B, each of the top and bottom surfaces of the substrate W has thereon the first liquid film LF1, which is a liquid film of the second rinse liquid.

In a process S102, the load cell 116 measures a first mass, which is a mass including the pin supporting member 114, the pins 115, the substrate W, the first liquid film LF1 attached to the top surface of the substrate W, and the first liquid film LF1 attached to the bottom surface of the substrate W. The load cell 116 transmits the measured first mass to the control device 9.

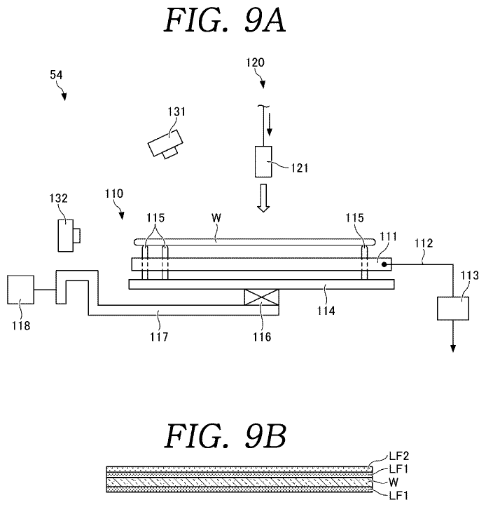

In a process S103, as shown in FIG. 9A, the nozzle 121 discharges a first amount of pure water toward the top surface of the substrate W. As a result, as shown in FIG. 9B, a second liquid film LF2, which is a liquid film of the pure water, is formed on the top surface of the substrate W.

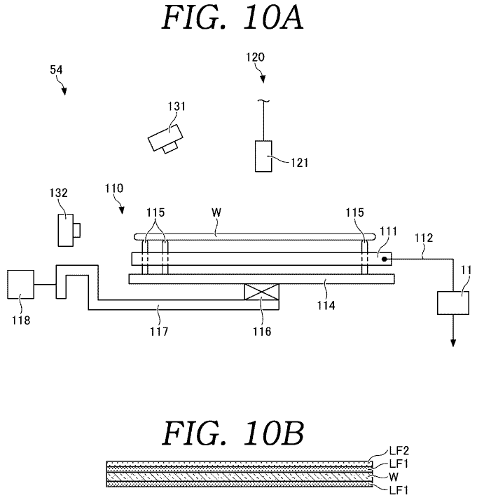

In a process S104, as shown in FIG. 10A, the nozzle 121 stops the discharge of the pure water to the substrate W. In this case, a state in which the second liquid film LF2 is formed on the top surface of the substrate W is maintained, as shown in FIG. 10B. Subsequently, the load cell 116 measures a second mass, which is a mass including the pin supporting member 114, the pins 115, the substrate W, the first liquid film LF1 attached to the top surface of the substrate W, the first liquid film LF1 attached to the bottom surface of the substrate W, and the second liquid film LF2. The load cell 116 transmits the measured second mass to the control device 9. The control device 9 calculates the mass of the second liquid film LF2 by subtracting the first mass from the second mass.

In a process S105, the control device 9 determines whether the mass of the second liquid film LF2 is equal to or greater than a first threshold. The first threshold is set as, for example, a lower limit mass of a monitoring range. When the mass of the second liquid film LF2 is equal to or greater than the first threshold (YES in the process S105), the control device 9 proceeds to a process S106. When the mass of the second liquid film LF2 is less than the first threshold (NO in the process S105), on the other hand, the control device 9 proceeds to a process S121. In the process S121, the nozzle 121 discharges the pure water again toward the top surface of the substrate W as much as the shortfall for the target value. After the process S121, the control device 9 returns the processing to the process S104.

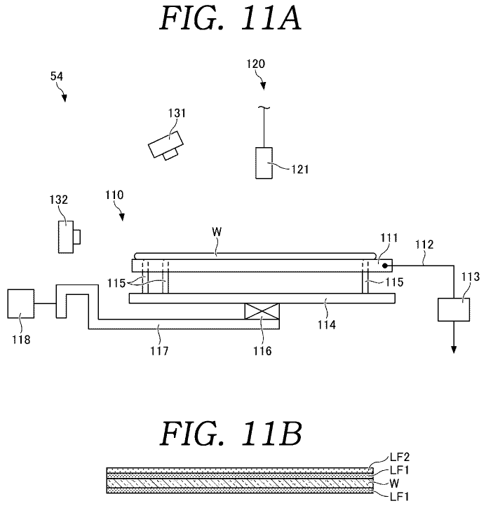

In the process S106, as shown in FIG. 11A, the driving source 118 lowers the arm 117 to lower the load cell 116, the pin supporting member 114, the pins 115, and the substrate W, thus allowing the substrate W to be placed on the stage 111. At this time, the state in which the second liquid film LF2 is formed on the top surface of the substrate W is maintained, as illustrated in FIG. 11B.

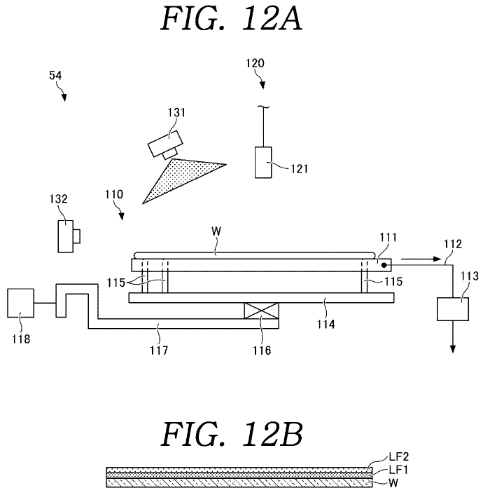

In a process S107, as shown in FIG. 12A, the ejector 113 sucks the first liquid film LF1 attached to the bottom surface of the substrate W through the suction path 112, and also attracts the substrate W so that is held on the stage 111. As a result, as shown in FIG. 12B, the first liquid film LF1 adhering to the bottom surface of the substrate W is removed. Although the process S107 can be started before the process S106 or in the middle of the process S106, it is desirable to start the process S107 after the process S106, that is, after the substrate W is disposed on the stage 111. This is because when the suction by the ejector 113 is started in the state that a gap exists between the stage 111 and the substrate W, air in the gap may be sucked in, resulting in deterioration in suction efficiency.

In a process S108, as shown in FIG. 12A, the first imaging device 131 images the top surface of the substrate W disposed on the stage 111 to acquire an top surface image, which is an image of the top surface of the substrate W. The first imaging device 131 transmits the acquired top surface image to the control device 9. The process S108 may be performed before the process S107 or simultaneously with the process S107.

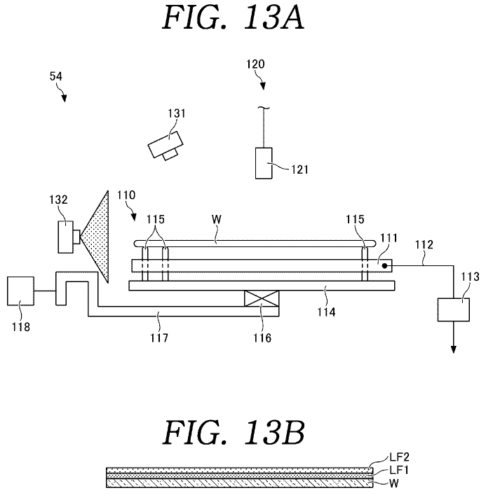

In a process S109, as shown in FIG. 13A, the driving source 118 raises the arm 117 to raise the load cell 116, the pin supporting member 114, the pins 115, and the substrate W, allowing the substrate W to be supported by the pins 115 while being distanced apart from the stage 111. At this time, the state in which the second liquid film LF2 is formed on the top surface of the substrate W is maintained, as illustrated in FIG. 13B.

In a process S110, the load cell 116 measures a third mass, which is a mass including the pin supporting member 114, the pins 115, the substrate W, and the first and second liquid films LF1 and LF2 attached to the top surface of the substrate W. In this case, since the first liquid film LF1 attached to the bottom surface of the substrate W is already removed as shown in FIG. 13B, the third mass does not include the mass of the first liquid film LF1 attached to the bottom surface of the substrate W. The load cell 116 transmits the measured third mass to the control device 9. The control device 9 calculates the mass of the first liquid film LF1 removed from the bottom surface of the substrate W by subtracting the third mass from the second mass.

In a process S111, as shown in FIG. 13A, the second imaging device 132 images the bottom surface of the substrate W supported by the pins 115 to acquire a bottom surface image, which is an image of the bottom surface of the substrate W. The second imaging device 132 transmits the acquired bottom surface image to the control device 9. The process S111 may be performed before the process S110 or simultaneously with the process S110.

In a process S112, the control device 9 determines whether the mass of the second liquid film LF2 is equal to or greater than a second threshold. The second threshold is a value greater than the first threshold. For example, the second threshold is set to a value greater than an upper limit mass of the monitoring range. By way of example, the second threshold is set to a value smaller than the mass at which the second liquid film LF2 adhering to the top surface of the substrate W is likely to droop when the fourth transfer device 61 transfers the substrate W at a normal transfer speed. When the mass of the second liquid film LF2 is equal to or greater than the second threshold (YES in the process S112), the control device 9 proceeds to a process S113. When the mass of the second liquid film LF2 is less than the second threshold (NO in the process S112), on the other hand, the control device 9 proceeds to a process S131.

In the process S113, the control device 9 determines whether the state of the second liquid film LF2 is normal based on the top surface image, and also determines whether the state of the bottom surface of the substrate W is normal based on the bottom surface image. For example, when the control device 9 recognizes based on the top surface image that the second liquid film LF2 is formed on the entire top surface of the substrate W, it makes a determination that the state of the second liquid film LF2 is normal. As another example, when the control device 9 recognizes based on the top surface image that the second liquid film LF2 is not formed on a portion (for example, an outer peripheral portion, a central portion, etc.) of the top surface of the substrate W, it makes a determination that the state of the second liquid film LF2 is abnormal. For another example, when the control device 9 recognizes based on the bottom surface image that the first liquid film LF1 does not remain on the bottom surface of the substrate W, it makes a determination that the state of the bottom surface of the substrate W is normal. For example, when the control device 9 recognizes based on the bottom surface image that the first liquid film LF1 remains on a portion (for example, an outer peripheral portion, a central portion, etc.) of the bottom surface of the substrate W, it makes a determination that the state of the bottom surface of the substrate W is abnormal. The control device 9 may store the state of the second liquid film LF2 (for example, information indicating normal or abnormal state) and the state of the bottom surface of the substrate W (for example, information indicating normal or abnormal state) in relation to information identifying the substrate W.

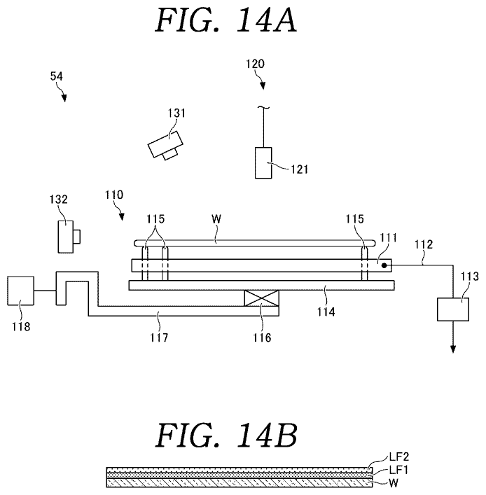

When the state of the second liquid film LF2 is normal and the state of the bottom surface of the substrate W is normal, the control device 9 transmits an instruction to the fourth transfer device 61 to transfer the substrate W supported by the pins 115 as shown in FIG. 14A at a low speed (process S114), and ends the processing. In this case, when the fourth transfer device 61 transfers the substrate W, it is possible to suppress the second liquid film LF2 from drooping from the substrate W. Here, the low-speed transfer means a transfer of the substrate W at a speed lower than a speed in a normal transfer where the substrate W is transferred at a normal speed. The transfer speed of the low-speed transfer may be equal to or less than half of the transfer speed of the normal transfer.

When the state of the second liquid film LF2 is normal and the state of the bottom surface of the substrate W is abnormal, the control device 9 returns the processing to the process S106. In this case, since the substrate W with the first liquid film LF1 remaining on the bottom surface thereof is not carried out from the second delivery table 54, the first liquid film LF1 may be suppressed from drooping from the bottom surface of the substrate W in the single-substrate processing section 6. Furthermore, since the processing proceeds back to the process S106, the first liquid film LF1 adhering to the bottom surface of the substrate W is removed again in the process S107.

When the state of the second liquid film LF2 is abnormal and the state of the bottom surface of the substrate W is normal, the control device 9 transmits an instruction to the fourth transfer device 61 to transfer the substrate W supported by the pins 115 as shown in FIG. 14A at a low speed (process S115), and ends the processing. When the mass of the second liquid film LF2 is equal to or greater than the second threshold and the state of the second liquid film LF2 is abnormal, if the pure water is re-discharged to the top surface of the substrate W, the second liquid film LF2 is likely to droop from the substrate W when the fourth transfer device 61 transfers the substrate W. Therefore, without re-discharging the pure water onto the top surface of the substrate W, the substrate W is transferred to the next liquid processing apparatus 62 and quickly processed therein. This makes it possible to suppress the second liquid film LF2 from drooping from the substrate W during the transfer, and also makes it easy to suppress a collapse of the irregularity pattern that might occur when the substrate W is dried.

When the state of the second liquid film LF2 is abnormal and the state of the bottom surface of the substrate W is abnormal, the control device 9 transmits an instruction to the fourth transfer device 61 to transfer the substrate W supported by the pins 115 as shown in FIG. 14A at a low speed (process S116), and ends the processing. When the mass of the second liquid film LF2 is equal to or greater than the second threshold and the state of the second liquid film LF2 is abnormal, if the pure water is re-discharged onto the top surface of the substrate W, the second liquid film LF2 is likely to droop from the substrate W when the fourth transfer device 61 transfers the substrate W. Therefore, without discharging the pure water onto the top surface of the substrate W, the substrate W is transferred to the next liquid processing apparatus 62 and quickly processed therein. This makes it possible to suppress the second liquid film LF2 from drooping from the substrate W during the transfer, and also makes it easy to suppress a collapse of the irregularity pattern that might occur when the substrate W is dried.

In the process S131, the control device 9 determines whether the state of the second liquid film LF2 is normal based on the top surface image, and determines whether the state of the bottom surface of the substrate W is normal based on the bottom surface image. The determination in the process S131 may be the same as the determination in the process S113.

When the state of the second liquid film LF2 and the state of the bottom surface of the substrate W are both normal, the control device 9 transmits an instruction to the fourth transfer device 61 to perform the normal transfer of the substrate W supported by the pins 115 as shown in FIG. 14A (process S132), and ends the processing. In the process S132, since the mass of the second liquid film LF2 is less than the second threshold, the second liquid film LF2 never or hardly droops from the substrate W even if the fourth transfer device 61 performs the normal transfer of the substrate W.

When the state of the second liquid film LF2 is normal and the state of the bottom surface of the substrate W is abnormal, the control device 9 returns the processing to the process S106. In this case, since the substrate W with the first liquid film LF1 remaining on the bottom surface thereof is not carried out from the second delivery table 54, the first liquid film LF1 may be suppressed from drooping from the bottom surface of the substrate W in the single-substrate processing section 6. Furthermore, since the processing proceeds back to the process S106, the first liquid film LF1 attached to the bottom surface of the substrate W is removed again in the process S107.

When the state of the second liquid film LF2 is abnormal and the state of the bottom surface of the substrate W is normal, the nozzle 121 re-discharges the pure water toward the top surface of the substrate W in an amount equal to or less than the shortfall for the upper limit mass of the monitoring range (process S133), and the control device 9 returns the processing to the process S104. In this case, the state of the second liquid film LF2 can be improved within a range in which the mass of the second liquid film LF2 does not reach or exceed the second threshold.

When the state of the second liquid film LF2 is abnormal and the state of the bottom surface of the substrate W is abnormal, the nozzle 121 discharges the pure water again toward the top surface of the substrate W in an amount equal to or less than the shortfall for the upper limit mass of the monitoring range (process S134), and the control device 9 returns the processing to the process S104. In this case, the state of the second liquid film LF2 can be improved within a range in which the mass of the second liquid film LF2 does not become equal to or greater than or equal to the second threshold.

According to the first example of the operation of the second delivery table 54 described above, the control device 9 makes a determination on the state of the second liquid film LF2 based on the top surface image when the mass of the second liquid film LF2 is equal to or greater than the first threshold. In this case, a defect in a coating processing can be detected with high accuracy.

Furthermore, according to the first example of the operation of the second delivery table 54, forming the second liquid film LF2 on the top surface of the substrate W (process S103) is performed immediately after the load cell 116 measures the first mass (process S102). This makes it easy to suppress the top surface of the substrate W from being dried.

### Second Example

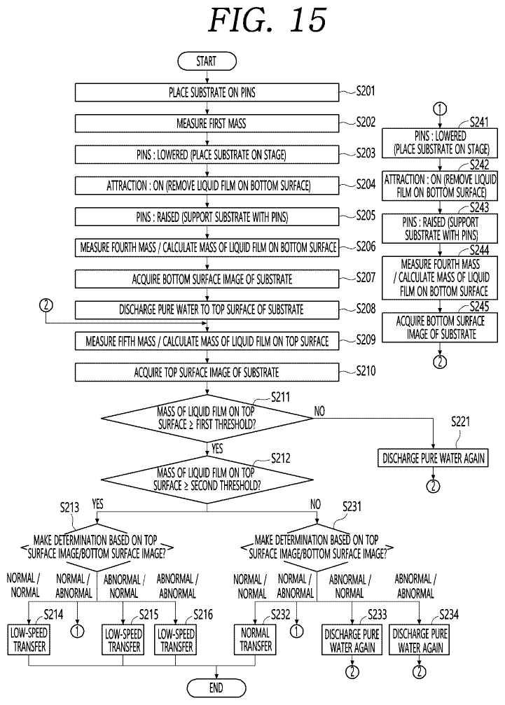

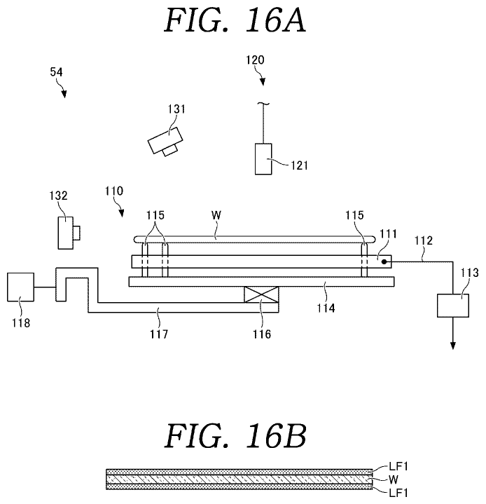

A second example of the operation of the second delivery table 54 will be described with reference to FIG. 15 to FIG. 22B. FIG. 15 is a flowchart illustrating the second example of the operation of the second delivery table 54. FIG. 16A to FIG. 22B are diagrams illustrating the second example of the operation of the second delivery table 54. In FIG. 16A to FIG. 22B, the diagrams assigned A are side views showing the second delivery table 54, and the diagrams assigned B are cross sectional views of the substrate W shown in the diagrams assigned A. The processing shown in FIG. 15 is performed under the control of the control device 9.

In a process S201, when the substrate W is transferred to the second delivery table 54 by the third transfer device 53, the substrate W is disposed on the three pins 115 as shown in FIG. 16A. At this time, as illustrated in FIG. 16B, each of the top and bottom surfaces of the substrate W has thereon the first liquid film LF1, which is a liquid film of the second rinse liquid.

In a process S202, the load cell 116 measures a first mass, which is a mass including the pin supporting member 114, the pins 115, the substrate W, the first liquid film LF1 attached to the top surface of the substrate W, and the first liquid film LF1 attached to the bottom surface of the substrate W. The load cell 116 transmits the measured first mass to the control device 9.

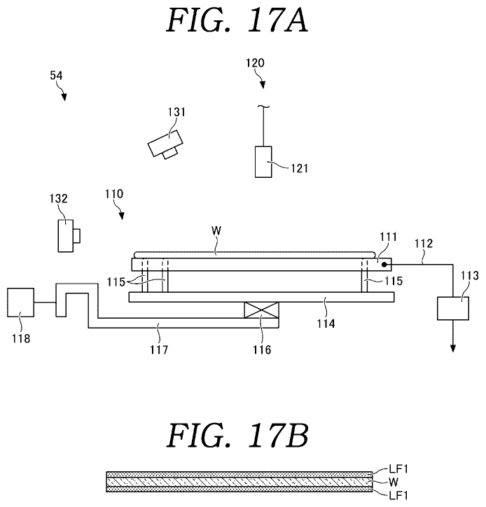

In a process S203, as shown in FIG. 17A, the driving source 118 lowers the arm 117 to lower the load cell 116, the pin supporting member 114, the pins 115, and the substrate W, thus allowing the substrate W to be placed on the stage 111. At this time, each of the top and bottom surfaces of the substrate W has thereon the first liquid film LF1, as illustrated in FIG. 17B.

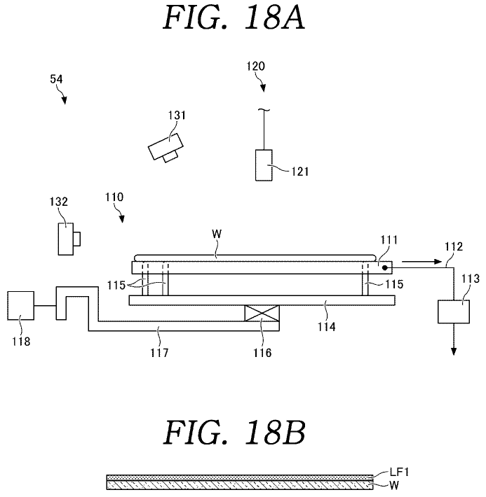

In a process S204, as shown in FIG. 18A, the ejector 113 sucks the first liquid film LF1 adhering to the bottom surface of the substrate W through the suction path 112, and also attracts the substrate W so that the substrate W is held on the stage 111. As a result, as shown in FIG. 18B, the first liquid film LF1 attached to the bottom surface of the substrate W is removed. Although the process S204 can be started before the process S203 or in the middle of the process S203, it is desirable to start the process S204 after the process S203, that is, after the substrate W is disposed on the stage 111. This is because when the suction by the ejector 113 is started in the state that a gap exists between the stage 111 and the substrate W, air in the gap may be sucked in, resulting in deterioration in suction efficiency.

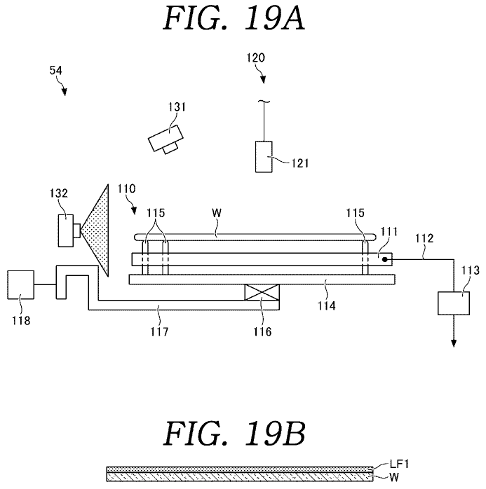

In a process S205, as shown in FIG. 19A, the driving source 118 raises the arm 117 to raise the load cell 116, the pin supporting member 114, the pins 115, and the substrate W, allowing the substrate W to be supported by the pins 115 while being distanced apart from the stage 111. At this time, the first liquid film LF1 remains on the top surface of the substrate W, as illustrated in FIG. 19B.

In a process S206, the load cell 116 measures a fourth mass, which is a mass including the pin supporting member 114, the pins 115, the substrate W, and the first liquid film LF1 attached to the top surface of the substrate W. In this case, since the first liquid film LF1 attached to the bottom surface of the substrate W is already removed as shown in FIG. 19B, the fourth mass does not include the mass of the first liquid film LF1 attached to the bottom surface of the substrate W. The load cell 116 transmits the measured fourth mass to the control device 9. The control device 9 calculates the mass of the first liquid film LF1 removed from the bottom surface of the substrate W by subtracting the fourth mass from the first mass.

In a process S207, as shown in FIG. 19A, the second imaging device 132 images the bottom surface of the substrate W supported by the pins 115 to acquire a bottom surface image, which is an image of the bottom surface of the substrate W. The second imaging device 132 transmits the acquired bottom surface image to the control device 9. The process S207 may be performed before the process S206 or simultaneously with the process S206.

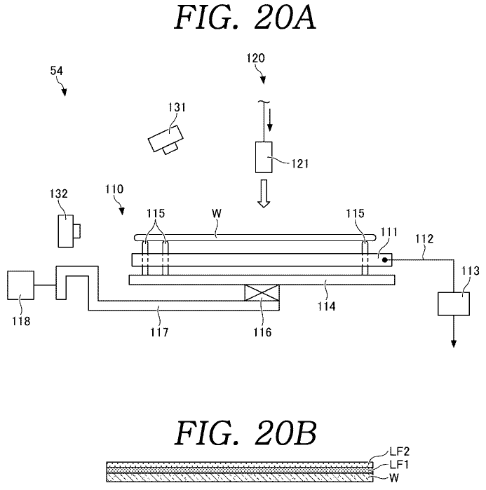

In a process S208, as shown in FIG. 20A, the nozzle 121 discharges a first amount of pure water toward the top surface of the substrate W. As a result, the second liquid film LF2 is formed on the top surface of the substrate W, as illustrated in FIG. 20B.

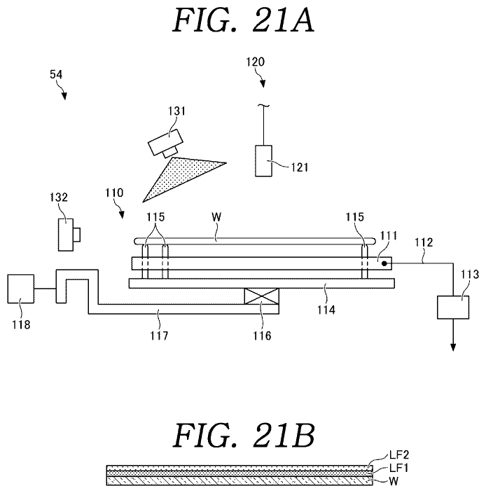

In a process S209, as shown in FIG. 21A, the nozzle 121 stops the discharge of the pure water to the substrate W. At this time, the state in which the second liquid film LF2 is formed on the top surface of the substrate W is maintained, as illustrated in FIG. 21B. Subsequently, the load cell 116 measures a fifth mass, which is a mass including the pin supporting member 114, the pins 115, the substrate W, and the first liquid film LF1 and the second liquid film LF2 attached to the top surface of the substrate W. At this time, since the first liquid film LF1 attached to the bottom surface of the substrate W is already removed as illustrated in FIG. 21B, the fifth mass does not include the mass of the first liquid film LF1 adhering to the bottom surface of the substrate W. The load cell 116 transmits the measured fifth mass to the control device 9. The control device 9 calculates the mass of the second liquid film LF2 by subtracting the fourth mass from the fifth mass.

In a process S210, as shown in FIG. 21A, the first imaging device 131 images the top surface of the substrate W supported by the pins 115 to acquire a top surface image, which is an image of the top surface of the substrate W. The first imaging device 131 transmits the acquired top surface image to the control device 9. The process S210 may be performed before the process S209 or simultaneously with the process S209.

In a process S211, the control device 9 determines whether the mass of the second liquid film LF2 is equal to or greater than a first threshold. When the mass of the second liquid film LF2 is equal to or greater than the first threshold (YES in the process S211), the control device 9 proceeds to a process S212. When the mass of the second liquid film LF2 is less than the first threshold (NO in the process S211), on the other hand, the control device 9 proceeds to a process S221. In the process S221, the nozzle 121 discharges the pure water again toward the top surface of the substrate W as much as the shortfall for the target value. After the process S221, the control device 9 returns the processing to the process S209.

In the process S212, the control device 9 determines whether the mass of the second liquid film LF2 is equal to or greater than a second threshold. When the mass of the second liquid film LF2 is equal to or greater than the second threshold (YES in the process S212), the control device 9 proceeds to a process S213. When the mass of the second liquid film LF2 is less than the second threshold (NO in the process S212), on the other hand, the control device 9 proceeds to a process S231.

In the process S213, the control device 9 determines whether the state of the second liquid film LF2 is normal based on the top surface image, and determines whether the state of the bottom surface of the substrate W is normal based on the bottom surface image. The determination in the process S213 may be the same as the determination in the process S113.

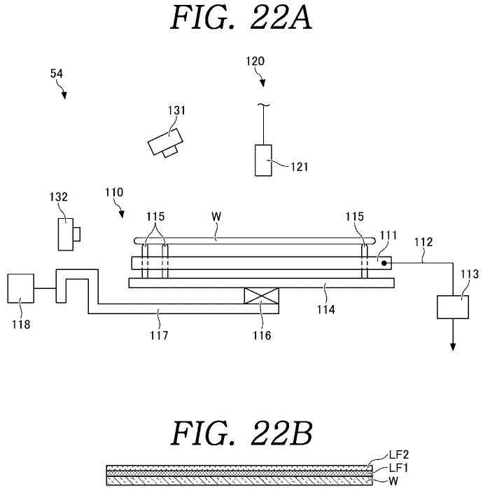

When the state of the second liquid film LF2 and the state of the bottom surface of the substrate W are both normal, the control device 9 transmits an instruction to the fourth transfer device 61 to transfer the substrate W supported by the pins 115 as shown in FIG. 22A at a low speed (process S214), and ends the processing. In this case, when the fourth transfer device 61 transfers the substrate W, it is possible to suppress the second liquid film LF2 from drooping from the substrate W.

When the state of the second liquid film LF2 is normal and the state of the bottom surface of the substrate W is abnormal, the control device 9 proceeds to a process S241. In processes S241 to S245, the control device 9 performs the same processes as in the processes S203 to S207, and then returns the processing to the process S209. In this case, since the substrate W with the first liquid film LF1 remaining on the bottom surface thereof is not carried out from the second delivery table 54, it is possible to suppress the first liquid film LF1 from drooping from the bottom surface of the substrate W in the single-substrate processing section 6. Furthermore, since the processing proceeds to the process S241, the first liquid film LF1 attached to the bottom surface of the substrate W is removed again in the process S242.

When the state of the second liquid film LF2 is abnormal and the state of the bottom surface of the substrate W is normal, the control device 9 transmits an instruction to the fourth transfer device 61 to transfer the substrate W supported by the pins 115 as shown in FIG. 22A at a low speed (process S215), and ends the processing. When the mass of the second liquid film LF2 is equal to or greater than the second threshold and the state of the second liquid film LF2 is abnormal, if the pure water is re-discharged to the top surface of the substrate W, the second liquid film LF2 is likely to droop from the substrate W when the fourth transfer device 61 transfers the substrate W. Therefore, without re-discharging the pure water to the top surface of the substrate W, the substrate W is transferred to the next liquid processing apparatus 62 and quickly processed therein. This makes it possible to suppress the second liquid film LF2 from drooping from the substrate W during the transfer, and also makes it easy to suppress a collapse of the irregularity pattern that might occur when the substrate is dried.

When the state of the second liquid film LF2 is abnormal and the state of the bottom surface of the substrate W is abnormal, the control device 9 transmits an instruction to the fourth transfer device 61 to transfer the substrate W supported by the pins 115 as shown in FIG. 22A at a low speed (process S216), and ends the processing. When the mass of the second liquid film LF2 is equal to or greater than the second threshold and the state of the second liquid film LF2 is abnormal, if the pure water is re-discharged to the top surface of the substrate W, the second liquid film LF2 is likely to droop from the substrate W when the fourth transfer device 61 transfers the substrate W. Therefore, without discharging the pure water to the top surface of the substrate W, the substrate W is transferred to the next liquid processing apparatus 62 and quickly processed therein. This makes it possible to suppress the second liquid film LF2 from drooping from the substrate W during the transfer, and also makes it easy to suppress a collapse of the irregularity pattern that might occur when the substrate W is dried.

In the process S231, the control device 9 determines whether the state of the second liquid film LF2 is normal based on the top surface image, and determines whether the state of the bottom surface of the substrate W is normal based on the bottom surface image. The determination in the process S231 may be the same as the determination in the process S213.

When the state of the second liquid film LF2 and the state of the bottom surface of the substrate W are both normal, the control device 9 transmits an instruction to the fourth transfer device 61 to perform a normal transfer of the substrate W supported by the pins 115 as shown in FIG. 22A (process S232), and ends the processing. In the process S232, since the mass of the second liquid film LF2 is less than the second threshold, the second liquid film LF2 never or hardly droops from the substrate W even if the fourth transfer device 61 performs the normal transfer of the substrate W.

When the state of the second liquid film LF2 is normal and the state of the bottom surface of the substrate W is abnormal, the control device 9 proceeds to a process S241. In processes S241 to S245, the control device 9 performs the same processes as in the processes S203 to S207, and then returns the processing to the process S209. In this case, since the substrate W with the first liquid film LF1 remaining on the bottom surface thereof is not carried out from the second delivery table 54, it is possible to suppress the first liquid film LF1 from drooping from the bottom surface of the substrate W in the single-substrate processing section 6. Furthermore, since the processing proceeds to the process S241, the first liquid film LF1 attached to the bottom surface of the substrate W is removed again in the process S242.

When the state of the second liquid film LF2 is abnormal and the state of the bottom surface of the substrate W is normal, the nozzle 121 re-discharges the pure water toward the top surface of the substrate W in an amount equal to or less than the shortfall for the upper limit mass of the monitoring range (process S233), and the control device 9 returns the processing to the process S209. In this case, the state of the second liquid film LF2 can be improved within a range in which the mass of the second liquid film LF2 does not reach or exceed the second threshold.

When the state of the second liquid film LF2 and the state of the bottom surface of the substrate W are both abnormal, the nozzle 121 discharges the pure water again toward the top surface of the substrate W in an amount equal to or less than the shortfall for the upper limit mass of the monitoring range (process S234), and the control device 9 returns the processing to the process S209. In this case, the state of the second liquid film LF2 can be improved within a range in which the mass of the second liquid film LF2 does not reach or exceed the second threshold.

According to the second example of the operation of the second delivery table 54 described above, the control device 9 makes a determination on the state of the second liquid film LF2 based on the top surface image when the mass of the second liquid film LF2 is equal to or greater than the first threshold. In this case, a defect in the coating processing can be detected with high accuracy.

In addition, according to the second example of the operation of the second delivery table 54, discharging of the pure water onto the top surface of the substrate W (process S208) is performed after the ejector 113 sucks and removes the first liquid film LF1 attached to the bottom surface of the substrate W (process S204). Therefore, it is possible to suppress the second liquid film LF2 formed on an outer peripheral portion of the substrate W from being sucked and lost.

### Third Example

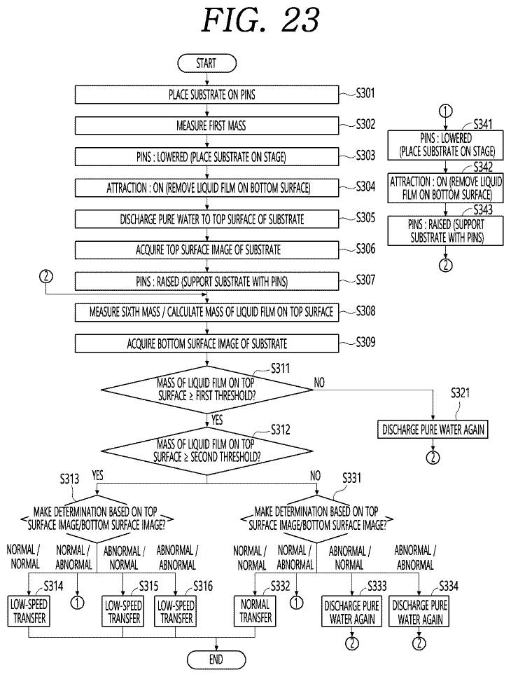

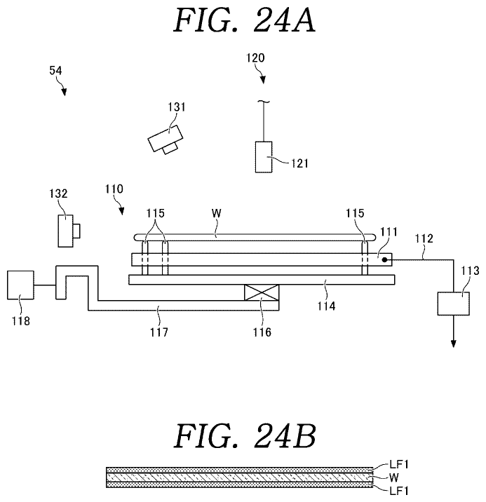

Referring to FIG. 23 to FIG. 29B, a third example of the operation of the second delivery table 54 will be described. FIG. 23 is a flowchart illustrating the third example of the operation of the second delivery table 54. FIG. 24A to FIG. 29B are diagrams showing the third example of the operation of the second delivery table 54. In FIG. 24A to FIG. 29B, the diagrams assigned A are side views showing the second delivery table 54, and the diagrams assigned B are cross sectional views of the substrate W shown in the diagrams assigned A. The processing shown in FIG. 23 is performed under the control of the control device 9.

In a process S301, when the substrate W is transferred to the second delivery table 54 by the third transfer device 53, the substrate W is disposed on the three pins 115 as shown in FIG. 24A. At this time, as shown in FIG. 24B, each of the top and bottom surfaces of the substrate W has thereon the first liquid film LF1, which is a liquid film of the second rinse liquid.

In a process S302, the load cell 116 measures a first mass, which is a mass including the pin supporting member 114, the pins 115, the substrate W, the first liquid film LF1 attached to the top surface of the substrate W, and the first liquid film LF1 attached to the bottom surface of the substrate W. The load cell 116 transmits the measured first mass to the control device 9.

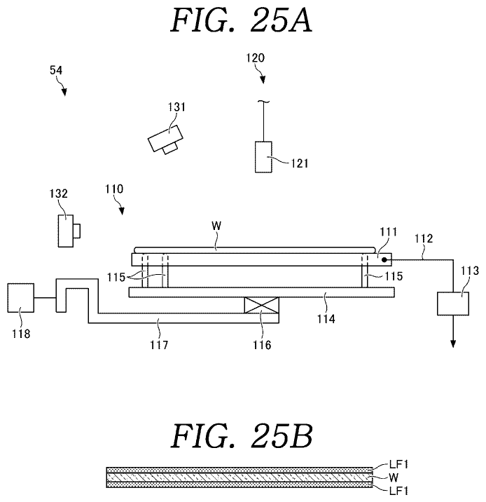

In a process S303, as shown in FIG. 25A, the driving source 118 lowers the arm 117 to lower the load cell 116, the pin supporting member 114, the pins 115, and the substrate W, allowing the substrate W to be placed on the stage 111. At this time, as shown in FIG. 25B, each of the top and bottom surfaces of the substrate W has the first liquid film LF1 formed thereon.

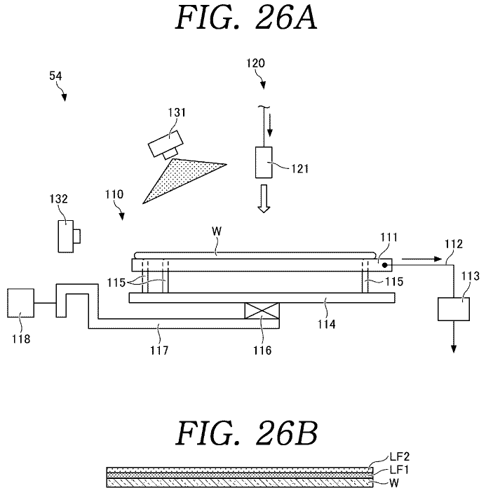

In a process S304, as shown in FIG. 26A, the ejector 113 sucks the first liquid film LF1 attached to the bottom surface of the substrate W through the suction path 112, and also attracts the substrate W so that the substrate W is held on the stage 111. As a result, as shown in FIG. 26B, the first liquid film LF1 adhering to the bottom surface of the substrate W is removed. Although the process S304 can be started before the process S303 or in the middle of process S303, it is desirable to start the process S304 after the process S303, that is, after the substrate W is disposed on the stage 111. This is because when the suction by the ejector 113 is started in the state that a gap exists between the stage 111 and the substrate W, air in the gap may be sucked in, resulting in deterioration in suction efficiency.

In a process S305, as shown in FIG. 26A, the nozzle 121 discharges a first amount of pure water toward the top surface of the substrate W. As a result, as shown in FIG. 26B, the second liquid film LF2 is formed on the top surface of the substrate W. In this case, since the substrate W is attracted on the stage 111, even if the substrate W is bent, pure water can be discharged toward the top surface of the substrate W in the state that the top surface of the substrate W is kept flat. Therefore, the second liquid film LF2 can be easily formed uniformly on the entire top surface of the substrate W.

In a process S306, the nozzle 121 stops the discharge of the pure water to the substrate W. At this time, as shown in FIG. 26B, the state in which the second liquid film LF2 is formed on the top surface of the substrate W is maintained. Subsequently, as illustrated in FIG. 26A, the first imaging device 131 images the top surface of the substrate W disposed on the stage 111 to acquire a top surface image, which is an image of the top surface of the substrate W. The first imaging device 131 transmits the acquired top surface image to the control device 9. Upon the completion of the process S306, the control device 9 may maintain the state in which the substrate W is attracted on the stage 111 without proceeding to the process S307 until an instruction to transfer the substrate W to the single-substrate processing section 6 is given. In this case, it is possible to suppress a part of the second liquid film LF2 from being chipped off.

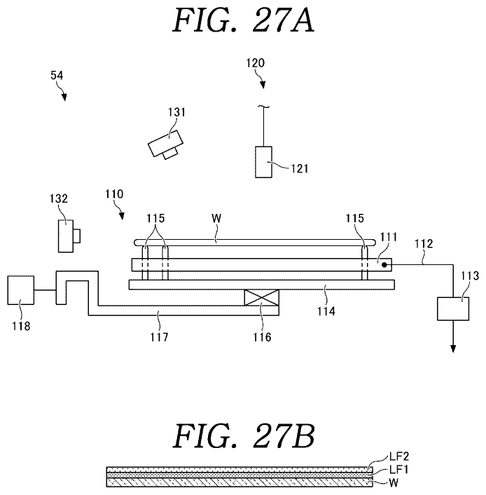

In a process S307, as shown in FIG. 27A, the driving source 118 raises the arm 117 to raise the load cell 116, the pin supporting member 114, the pins 115, and the substrate W, allowing the substrate W to be supported by the pins 115 while being distanced apart from the stage 111. At this time, as shown in FIG. 27B, the state in which the second liquid film LF2 is formed on the top surface of the substrate W is maintained.

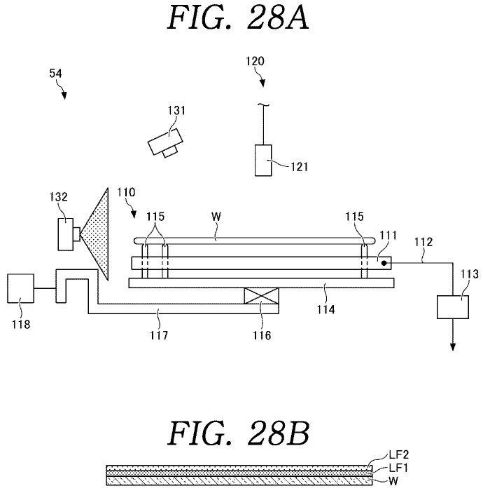

In a process S308, the load cell 116 measures a sixth mass, which is a mass including the pin supporting member 114, the pins 115, the substrate W, and the first and second liquid films LF1 and LF2 attached to the top surface of the substrate W. At this time, since the first liquid film LF1 attached to the bottom surface of the substrate W is removed as illustrated in FIG. 28B, the sixth mass does not include the mass of the first liquid film LF1 attached to the bottom surface of the substrate W. The load cell 116 transmits the measured sixth mass to the control device 9. The control device 9 calculates the mass of the second liquid film LF2 by subtracting the first mass and a predetermined mass from the sixth mass. Here, the predetermined mass may be an estimated mass, which is a mass of the first liquid film LF1 estimated to be removed from the bottom surface of the substrate W. The predetermined mass may be determined in advance before the processing shown in FIG. 23 is started. In the third example, since the mass of the first liquid film LF1 removed from the bottom surface of the substrate W is not calculated, the predetermined mass is used.

In a process S309, as shown in FIG. 28A, the second imaging device 132 images the bottom surface of the substrate W supported by the pins 115 to acquire a bottom surface image, which is an image of the bottom surface of the substrate W. The second imaging device 132 transmits the acquired bottom surface image to the control device 9. The process S309 may be performed before the process S308 or simultaneously with the process S308.

In a process S311, the control device 9 determines whether the mass of the second liquid film LF2 is equal to or greater than a first threshold. When the mass of the second liquid film LF2 is equal to or greater than the first threshold (YES in the process S311), the control device 9 proceeds to a process S312. When the mass of the second liquid film LF2 is less than the first threshold (NO in the process S311), on the other hand, the control device 9 proceeds to a process S321. In the process S321, the nozzle 121 discharges the pure water again toward the top surface of the substrate W as much as the shortfall for the target value. Upon the completion of the process S321, the control device 9 returns the processing to the process S308.

In a process S312, the control device 9 determines whether the mass of the second liquid film LF2 is equal to or greater than a second threshold. When the mass of the second liquid film LF2 is equal to or greater than the second threshold (YES in the process S312), the control device 9 proceeds to a process S313. When the mass of the second liquid film LF2 is less than the second threshold (NO in the process S312), on the other hand, the control device 9 proceeds to a process S331.

In the process S313, the control device 9 determines whether the state of the second liquid film LF2 is normal based on the top surface image, and determines whether the state of the bottom surface of the substrate W is normal based on the bottom surface image. The determination in the process S313 may be the same as the determination in the process S113.

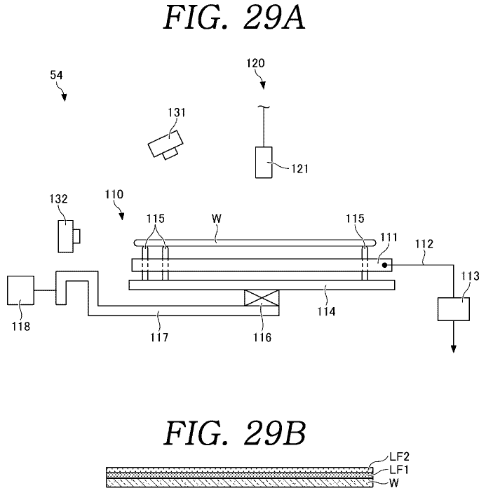

When the state of the second liquid film LF2 and the state of the bottom surface of the substrate W are both normal, the control device 9 transmits an instruction to the fourth transfer device 61 to transfer the substrate W supported by the pins 115 as shown in FIG. 29A at a low speed (process S314), and ends the processing. In this case, when the fourth transfer device 61 transfers the substrate W, it is possible to suppress the second liquid film LF2 from drooping from the substrate W.

When the state of the second liquid film LF2 is normal and the state of the bottom surface of the substrate W is abnormal, the control device 9 proceeds to a process S341. In processes S341, S342, and S343, the control device 9 performs the same processes as in the processes S303, S304, and S307, and then returns the processing to the process S308. In this case, since the substrate W with the first liquid film LF1 remaining on the bottom surface thereof is not taken out from the second delivery table 54, the first liquid film LF1 may be suppressed from drooping from the bottom surface of the substrate W in the single-substrate processing section 6. Furthermore, since the processing proceeds to the process S341, the first liquid film LF1 attached to the bottom surface of the substrate W is removed again in the process S342.

When the state of the second liquid film LF2 is abnormal and the state of the bottom surface of the substrate W is normal, the control device 9 transmits an instruction to the fourth transfer device 61 to transfer the substrate W supported by the pins 115 as shown in FIG. 29A at a low speed (process S315), and ends the processing. When the mass of the second liquid film LF2 is equal to or greater than the second threshold and the state of the second liquid film LF2 is abnormal, if the pure water is re-discharged to the top surface of the substrate W, the second liquid film LF2 is likely to droop from the substrate W when the fourth transfer device 61 transfers the substrate W. Therefore, without re-discharging the pure water onto the top surface of the substrate W, the substrate W is transferred to the next liquid processing apparatus 62 and quickly processed therein. This makes it possible to suppress the second liquid film LF2 from drooping from the substrate W during the transfer, and also makes it easy to suppress a collapse of the irregularity pattern that might occur when the substrate W is dried.

When the state of the second liquid film LF2 and the state of the bottom surface of the substrate W are both abnormal, the control device 9 transmits an instruction to the fourth transfer device 61 to transfer the substrate W supported by the pins 115 as shown in FIG. 29A at a low speed (process S316), and ends the processing. When the mass of the second liquid film LF2 is equal to or greater than the second threshold and the state of the second liquid film LF2 is abnormal, if the pure water is re-discharged onto the top surface of the substrate W, the second liquid film LF2 is likely to droop from the substrate W when the fourth transfer device 61 transfers the substrate W. Therefore, without discharging the pure water onto the top surface of the substrate W, the substrate W is transferred to the next liquid processing apparatus 62 and quickly processed therein. This makes it possible to suppress the second liquid film LF2 from drooping from the substrate W during the transfer, and also makes it easy to suppress a collapse of the irregularity pattern that might occur when the substrate W is dried.

In a process S331, the control device 9 determines whether the state of the second liquid film LF2 is normal based on the top surface image, and determines whether the state of the bottom surface of the substrate W is normal based on the bottom surface image. The determination in the process S331 may be the same as the determination in the process S313.

When the state of the second liquid film LF2 and the state of the bottom surface of the substrate W are both normal, the control device 9 transmits an instruction to the fourth transfer device 61 to perform a normal transfer of the substrate W supported by the pins 115 as shown in FIG. 29A (process S332), and ends the processing. In the process S332, since the mass of the second liquid film LF2 is less than the second threshold, the second liquid film LF2 never or hardly droop from the substrate W even if the fourth transfer device 61 performs the normal transfer of the substrate W.

When the state of the second liquid film LF2 is normal and the state of the bottom surface of the substrate W is abnormal, the control device 9 proceeds to the process S341. In processes S341, S342, and S343, the control device 9 performs the same processes as in the processes S303, S304, and S307, and then returns the processing to process S308. In this case, since the substrate W with the first liquid film LF1 remaining on the bottom surface thereof is not taken out from the second delivery table 54, the first liquid film LF1 may be suppressed from drooping from the bottom surface of the substrate W in the single-substrate processing section 6. Further, since the processing proceeds to the process S341, the first liquid film LF1 adhering to the bottom surface of the substrate W is removed again in the process S342.

When the state of the second liquid film LF2 is abnormal and the state of the bottom surface of the substrate W is normal, the nozzle 121 re-discharges the pure water toward the top surface of the substrate W in an amount equal to or less than the shortfall for the upper limit mass of the monitoring range (process S333), and the control device 9 returns the processing to the process S308. In this case, the state of the second liquid film LF2 can be improved within a range in which the mass of the second liquid film LF2 does not reach or exceed the second threshold.

When the state of the second liquid film LF2 and the state of the bottom surface of the substrate W are both abnormal, the nozzle 121 discharges the pure water again toward the top surface of the substrate W in an amount equal to or less than the shortfall for the upper limit mass of the monitoring range (process S334), and the control device 9 returns the processing to the process S308. In this case, the state of the second liquid film LF2 can be improved within a range in which the mass of the second liquid film LF2 does not become equal to or greater than the second threshold.

According to the third example of the operation of the second delivery table 54 described above, the control device 9 makes a determination on the state of the second liquid film LF2 based on the top surface image when the mass of the second liquid film LF2 is equal to or greater than the first threshold. In this case, a defect in the coating processing can be detected with high accuracy.

Also, according to the third example of the operation of the second delivery table 54, the nozzle 121 discharges the pure water toward the top surface of the substrate W in the state that the substrate W is attracted to the stage 111. Therefore, even when the substrate W is bent, the pure water can be discharged toward the top surface of the substrate W in the state that the top surface of the substrate W is kept flat. This makes it easy to uniformly form the second liquid film LF2 on the entire top surface of the substrate W.

Here, it should be noted that the above-described exemplary embodiments are illustrative in all aspects and are not anyway limiting. The above-described exemplary embodiments may be omitted, replaced and modified in various ways without departing from the scope and the spirit of claims.

According to the exemplary embodiment, it is possible to accurately detect the defect in the coating processing.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

We claim:

1. A substrate standby device configured to allow a substrate to standby, the substrate having a first liquid film adhering to a top surface and a bottom surface thereof, the substrate standby device comprising:
a processing liquid supply configured to supply a processing liquid to the top surface of the substrate;
a mass measuring device configured to measure a mass of the substrate;
a first imaging device configured to acquire a top surface image, which is an image of the top surface of the substrate; and
a controller,
wherein the controller performs:
forming a second liquid film by supplying, from the processing liquid supply, a first amount of the processing liquid to the top surface of the substrate;
measuring a mass of the second liquid film based on the mass of the substrate measured by the mass measuring device;
acquiring the top surface image with the first imaging device; and
determining a state of the second liquid film based on the top surface image when the mass of the second liquid film is equal to or greater than a first threshold.

2. The substrate standby device of claim 1, further comprising:
a suction mechanism configured to suction the bottom surface of the substrate,
wherein the controller further performs removing the first liquid film adhering to the bottom surface of the substrate by suctioning the bottom surface of the substrate with the suction mechanism.

3. The substrate standby device of claim 2,
wherein the measuring of the mass of the second liquid film comprises:
measuring a first mass of the substrate including the first liquid film adhering to the top surface and the first liquid film adhering to the bottom surface but not including the second liquid film;
measuring a second mass of the substrate including the first liquid film adhering to the top surface, the first liquid film adhering to the bottom surface, and the second liquid film; and
calculating the mass of the second liquid film based on the first mass and the second mass.

4. The substrate standby device of claim 2,
wherein the measuring of the mass of the second liquid film comprises:
measuring a fourth mass of the substrate including the first liquid film adhering to the top surface but not including the first liquid film adhering to the bottom surface and the second liquid film;
measuring a fifth mass of the substrate including the first liquid film adhering to the top surface, not including the first liquid film adhering to the bottom surface, and including the second liquid film; and
calculating the mass of the second liquid film based on the fourth mass and the fifth mass.

5. The substrate standby device of claim 2,
wherein the measuring of the mass of the second liquid film comprises:
measuring a first mass of the substrate including the first liquid film adhering to the top surface and the first liquid film adhering to the bottom surface but not including the second liquid film;
measuring a sixth mass of the substrate including the first liquid film adhering to the top surface, not including the first liquid film adhering to the bottom surface, and including the second liquid film; and
calculating the mass of the second liquid film based on the first mass and the sixth mass.

6. The substrate standby device of claim 2, further comprising:
a stage configured to hold the substrate horizontally,
wherein the stage has multiple suction holes connected to the suction mechanism.

7. The substrate standby device of claim 6, further comprising:
multiple pins configured to support the substrate; and
a driving source configured to move the multiple pins up and down with respect to the stage.

8. The substrate standby device of claim 1, further comprising:
a second imaging device configured to acquire a bottom surface image, which is an image of the bottom surface of the substrate.

9. The substrate standby device of claim 8,
wherein the controller changes a processing on the substrate based on the top surface image and the bottom surface image.

10. A substrate processing system comprising a substrate standby device as claimed in claim 1.

11. A substrate processing method, comprising:
supplying a first amount of processing liquid to a top surface of a substrate to form a second liquid film, the substrate having a first liquid film adhering to the top surface and a bottom surface thereof;
measuring a mass of the substrate on which the second liquid film is formed;
measuring a mass of the second liquid film based on the mass of the substrate;
acquiring a top surface image, which is an image of the top surface of the substrate; and
determining a state of the second liquid film based on the top surface image when the mass of the second liquid film is equal to or greater than a first threshold.
